(19) United States
(12) Patent Application Publication
(10) Pub. No.: US 2023/0187118 A1
(43) Pub. Date: Jun. 15, 2023

(54) INDUCTIVE COMPONENT AND MANUFACTURING METHOD

(71) Applicants: STMicroelectronics (Grenoble 2) SAS, Grenoble (FR); STMicroelectronics (Tours) SAS, Tours (FR)

(72) Inventors: Ludovic FOURNEAUD, Saint Vincent de Mercuze (FR); Laurent MOINDRON, Vernou sur Brenne (FR); Gregory BOUTELOUP, Venon (FR)

(73) Assignees: STMicroelectronics (Grenoble 2) SAS, Grenoble (FR); STMicroelectronics (Tours) SAS, Tours (FR)

(21) Appl. No.: 18/074,813

(22) Filed: Dec. 5, 2022

(30) Foreign Application Priority Data
Dec. 14, 2021 (FR) 2113430

(51) Int. Cl. H01F 27/28; H01F 27/02; H01F 41/04; H01L 23/498; H01L 23/31

(52) U.S. Cl. CPC H01F 27/2804; H01F 27/022; H01F 41/041; H01L 23/3107; H01L 23/49822; H01L 28/10

(57) ABSTRACT

An integrated circuit device includes at least one inductive component with at least one integrated metal winding that is at least partially embedded in a coating. The coating includes at least one ferromagnetic material. The coating optionally includes a non-magnetic material, for example a dielectric.

### PRIORITY CLAIM

This application claims the priority benefit of French Application for Patent No. 2113430, filed on Dec. 14, 2021, the content of which is hereby incorporated by reference in its entirety to the maximum extent allowable by law.

### TECHNICAL FIELD

Embodiments and implementations relate to microelectronics, in particular inductive components and those used, for example, to create transformers.

### BACKGROUND

At present, there are discrete components incorporating metal coils forming inductors. However, besides the fact that such inductors can have unsatisfactory performance for certain uses, such discrete components have sizes making them impossible to integrate at the substrate level of the packages of integrated circuits (between the chip and a printed circuit board) and making them very bulky at the printed circuit board level.

There are also inductors formed by spiral metal tracks, etched and formed in a stack of dielectric and metal layers of a substrate of an integrated circuit package. The value of the inductance is provided by the length of the metal track and the number of windings, but such an inductor has mediocre electromagnetic performance induced by the non-magnetic characteristic of the dielectric materials used and the low number of windings that can be created.

There is therefore currently a need to have, for certain uses in microelectronics, compact inductive components, or inductors, that can have high inductive values with improved performance such as an improved quality factor (Q factor) and reduced losses for example such as a reduction of the parasite resistance and of the magnetic flux losses.

### SUMMARY

According to one aspect, a device is thus proposed comprising at least one integrated inductive component including at least one metal winding at least partially embedded in a coating including at least one ferromagnetic material and optionally also a non-magnetic material, for example a dielectric material.

An integrated inductive component, unlike a discrete component, is easily integrated into an integrated circuit package, for example, and has a competitive manufacturing price.

The presence of the ferromagnetic material contributes to increasing the electromagnetic performance of the inductive component and to increasing component integration.

For example, the use of a metal winding at least partially embedded in a ferromagnetic material allows a reduction of the parasite resistance and of the magnetic flux losses.

High inductive values with a high quality factor can also be obtained with such an integrated component, which is particularly compact.

The ferromagnetic material is chosen according to the characteristics desired for the inductor given the intended use.

For example, the ferromagnetic material can be a hardened resin.

This hardened resin can include a dielectric material such as a polymer, for example nylon 6, nylon 12, or a polyamide, including a magnetic material that comprises, for example, a strontium (Sr) ferrite, a neodymium-iron-boron alloy (NdFeB), a CoZrO alloy which has high-frequency performance suitable for radiofrequency uses, a cobalt-nickel-iron (CoNiFe) alloy, or amorphous iron-cobalt alloys, or any combination of at least some of the elements mentioned above.

A person skilled in the art will be able to choose the composition of the ferromagnetic material according to the properties desired for the inductive component given the intended use.

The metal winding can include at least one flat metal track having a shape suitable for creating an inductive element, for example in the shape of a spiral or having a solenoidal shape.

The metal winding can also include several flat metal tracks respectively located in parallel planes, electrically connected and mutually separated at least for some of them by the ferromagnetic material.

Some tracks can be mutually separated by the non-magnetic material.

This electric connection between the tracks of the various planes can be carried out via vias, hollow or solid, having any cross-section, for example circular, square, rectangular...

The metal winding can be totally embedded in said coating.

According to one implementation, the metal winding includes two ends, and the coating includes several faces, and the device thus includes two metal contacts respectively located at the two ends and opening at least onto one of the faces of the coating.

These two metal contacts can thus allow, for example, an electric connection of the inductive component to other components and/or a connection of the inductive component onto a conventional supporting substrate of an integrated circuit package, for example a multilayer supporting substrate of the PCB type.

This being according to a particularly advantageous alternative, the coating can itself form a supporting substrate.

If the coating only includes a ferromagnetic material, a magnetic supporting substrate is thus obtained.

If the coating includes a ferromagnetic material and a non-magnetic material, a magnetic-non-magnetic, for example magneto-dielectric, hybrid supporting substrate is obtained.

This can be advantageous when it is desired to create a device forming a high-performance transformer including a first inductive component (the primary) embedded in a ferromagnetic material and a second inductive component (the secondary) embedded in a ferromagnetic material, the two elements being separated by a dielectric resin allowing to create a galvanic insulation.

A hybrid supporting substrate, including certain turns insulated by a non-magnetic, for example dielectric, material instead of being separated by the magnetic material, allows the choice of coupling or uncoupling certain turns inside the supporting substrate.

The supporting substrate has two opposite faces, for example a mounting face, the other face, for example the lower face, including electrically conductive connection means.

An encapsulation body can be fastened onto the mounting face so as to form an integrated circuit package.

In this particularly advantageous alternative, two functions are thus carried out with the same means, namely the ferromagnetic coating.

A first function is to contribute to creating the inductive component and to contribute to obtaining good electromagnetic performance, even with metal windings having small sizes.

A second function is to form a supporting substrate and, in this respect, as indicated above, the coating thus has a mounting face and a lower face including electrically conductive connection means, for example solder balls, allowing its connection, for example, onto a printed circuit board (PCB).

The device can thus further include, as indicated above, an encapsulation body, such as a cover or a molding resin, fastened onto the mounting face of the supporting substrate (the coating), so as to form an integrated circuit package.

If a molding resin is used to form the encapsulation body, it can be different from the ferromagnetic resin or also be the same ferromagnetic resin.

According to this alternative in which the coating forms the supporting substrate, the coating can further include at least one integrated circuit located in the coating in a zone distinct from that containing the metal winding.

The mounting face of the coating forming the supporting substrate can also support at least one electronic chip encapsulated by the encapsulation body.

According to another possible alternative, the device can comprise a supporting substrate having a mounting face supporting said at least one integrated inductive component.

This supporting substrate can be, for example, a multilayer supporting substrate of an integrated circuit package.

Also, in this alternative, the device can include at least one electronic chip, said at least one integrated inductive component supporting said at least one electronic chip.

It is also possible for the supporting substrate to also support at least one electronic chip located on the mounting face of the supporting substrate laterally with respect to said at least one inductive component.

Also, according to this alternative, the device can include at least one integrated circuit located in the coating in a zone distinct from that containing the metal winding.

Here again, the device can further include an encapsulation body, for example a cover or a molding resin, fastened onto the mounting face of the supporting substrate and encapsulating said at least one inductive component and said at least one optional chip, so as to form an integrated circuit package.

According to another aspect, a method for manufacturing an integrated inductive component is proposed, comprising: a) forming at least one metal winding at least partially embedded in a coating including at least one ferromagnetic material and optionally also a non-magnetic, for example dielectric, material.

As indicated above, such a ferromagnetic material can be, for example, a thermoset magnetic resin.

This thermoset resin can result for example from a polymerization at ambient temperature of a resin initially in liquid or viscous form.

This initial resin can be deposited, for example, using a liquid, a fine film, a powder of a dielectric material such as that mentioned above, mixed with a magnetic material such as that mentioned above in the form of liquid, a fine film, a powder, granular films, etc., and any combinations of at least some of the above elements.

According to one embodiment, the metal winding includes at least one first flat metal track in the shape of a spiral, and step a) includes the steps of: a1) forming, above a first face of a support, a first layer of the ferromagnetic material having a free face; and a2) forming said at least one first metal track in the shape of a spiral on said free face.

According to one embodiment the metal winding comprises forming a second layer of the ferromagnetic material encapsulating said at least one first flat metal track.

According to one embodiment the metal winding comprises a formation of a first and a second electrically conductive stud above the first face of the support, respectively intended to be in contact with a first end and a second end of the metal winding.

According to one embodiment, the first stud is in contact with a first end of the first metal track and the second stud is not in contact with this first metal track, and step a) comprises: after step a2) and before step a3), the steps of: a20) forming a first and of a second electrically conductive via respectively connecting a second free end of the first metal track and the second stud, and after step a3); and a4) forming a second metal track in the shape of a spiral on the second layer of ferromagnetic material, the two ends of this second metal track respectively contacting the two vias.

According to one embodiment the method further comprises forming a third layer of the ferromagnetic material encapsulating said second flat metal track.

At this stage three metallization levels have been created in the coating, two of the levels of which include two metal tracks in the shape of spirals of the metal winding.

Of course, it could have been possible to create only a single metal track in the shape of a spiral. It is also possible to repeat some of the above steps to create other metal tracks in the shape of a spiral of the metal winding.

It is also possible for the method to comprise at least one replacement of a layer of ferromagnetic material by a layer of a non-magnetic material so as to obtain at least one non-magnetic layer adjacent to a ferromagnetic layer.

A galvanic insulation can thus be created between turns.

During the formation of the turns on each of the levels, it is also possible to form additional tracks only being used for the interconnection of a chip integrated into the device with the lower face provided with solder balls for example, or only being used for the interconnection of several chips integrated into the device.

According to one alternative embodiment the method further comprises removing the support after step a).

According to another possible alternative embodiment, the support is a multilayer supporting substrate that is preserved after step a).

### BRIEF DESCRIPTION OF THE DRAWINGS

Other advantages and features of the invention will appear upon examining the detailed description of implementations and embodiments, in no way limiting, and the appended drawings in which:

FIG. 1 shows a device including an integrated inductive component;

FIGS. 2-3 illustrate spiral shapes of metal tracks;

FIGS. 4-6 illustrate integrated circuit package embodiments including the integrated inductive component with an encapsulation body;

FIGS. 7-8 illustrate integrated circuit package embodiments including the integrated inductive component with an encapsulation body and supporting substrate;

FIGS. 9-20 to describe an embodiment of a method for manufacturing an integrated inductive component; and

FIGS. 21-31 illustrate another embodiment of a method for manufacturing a device.

### DETAILED DESCRIPTION

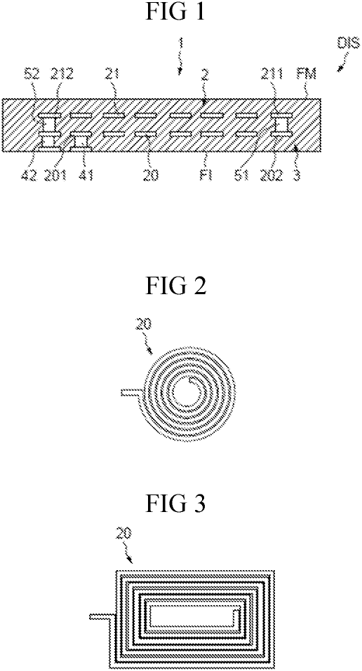

In FIG. 1, the reference DIS designates a device including here an integrated inductive component 1.

This component 1 comprises a metal winding 2 here totally embedded in a ferromagnetic coating 3 which includes a lower face FI and an upper face FM.

In this example, the ferromagnetic material forming the coating 3 is a hardened resin.

This hardened resin can include a dielectric material such as a polymer (for example nylon 6, or nylon 12), or a polyamide including a magnetic material (for example, a strontium (Sr) ferrite, a neodymium-iron-boron alloy (NdFeB), a CoZrO alloy, which has high-frequency performance suitable for radiofrequency uses, a cobalt-nickel-iron (CoNiFe) alloy, or amorphous iron-cobalt alloys, or any combination of at least some of the elements mentioned above).

A person skilled in the art will be able to choose the composition of the ferromagnetic material according to the properties desired for the inductive component given the intended use.

As a non-limiting example, such a resin can be the resin AFT INNOVA from the Japanese company AJINOMOTO, which has good electromagnetic performance at 100 MHz and which can, for example, be used in switched-mode power supplies operating up to this frequency.

In the implementation of FIG. 1, the metal winding 2 comprises a first metal track 20 in the shape of a spiral and a second metal track 21 also in the shape of a spiral, located in two parallel planes, here at the second and third levels of metal.

As a non-limiting example, the two tracks 20 and 21 can be separated by a thickness of resin between approximately ten micrometers and several hundred micrometers, for example approximately 20 to 160 micrometers.

The first metal track 20 includes a first end 201 and a second end 202.

The second metal track 21 includes a first end 211 and a second end 212.

The first end 201 forms the first end of the metal winding while the second end 212 forms the second end of the metal winding.

The component 1 also includes a first contact or pillar 41 in contact with the first end 201 and also opening onto the lower face FI of the coating 3.

The component 1 also includes a first metal via 51 connecting the second end 202 and the first end 211.

The component 1 also includes a second via 52 connecting the second end 212 to a second contact or pillar 42 also opening onto the lower face FI of the coating 3.

The free surfaces of the contacts or pillars 41 and 42 allow, for example, to connect the inductive component 1 to another circuit or to weld this component onto a conventional carrier substrate, for example multilayer, of an integrated circuit package.

The metal used for the metal winding as well as the pillars and vias can be, for example, made of copper.

The spiral of each metal track can have any shape.

It can have, for example, a circular shape as schematically illustrated in FIG. 2 for the track 20 or a rectangular shape as schematically illustrated in FIG. 3.

For example, the length of each track can be approximately one hundred millimeters with a number of turns of approximately ten for a surface of inductive element of 4 x4mm².

By using an AFT INNOVA resin, an inductive value of approximately 95 nH to 100 MHz can be obtained for a length of track of 47 mm and 3 turns, while an inductive value of only 50 nH would be obtained by using a non-ferromagnetic conventional molding resin.

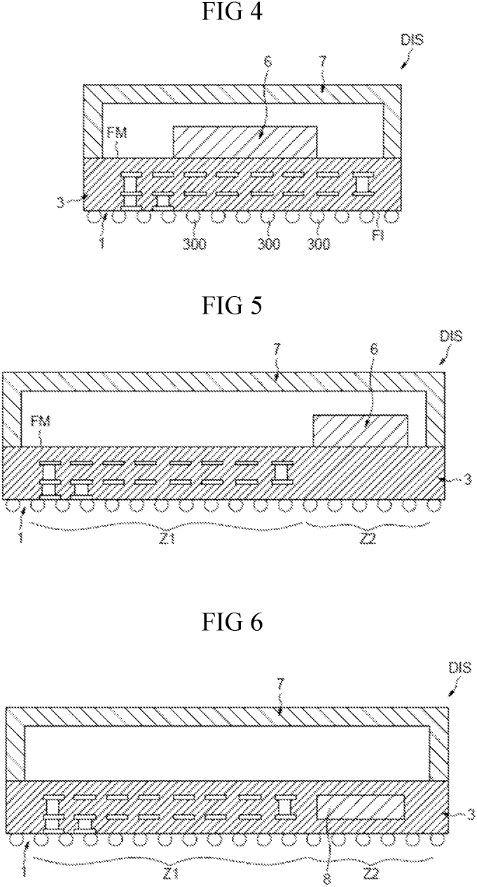

As schematically illustrated in FIGS. 4 to 6, the coating 3 can itself form a supporting substrate having a mounting face FM which is the upper face here and a lower face FI which includes electrically conductive connection 300, for example but not limitingly solder balls, allowing for example the supporting substrate to be fastened onto a printed circuit board.

The device DIS can also include an encapsulation body 7, for example a cover here, fastened onto the mounting face so as to form an integrated circuit package.

This encapsulation body could also be a molding resin.

As illustrated in FIG. 4, the device DIS can also include at least one electronic integrated circuit chip 6 supported by the integrated inductive component 1.

The encapsulation body 7 can thus be optionally a molding resin encapsulating the chip 6.

It is also possible, as illustrated in FIG. 5, for the coating 3 (supporting substrate) to support an electronic chip 6 located above a zone Z2 distinct from the zone Z1 in which the metal winding of the inductive component 1 is located whereas in FIG. 4, the chip 6 was located above the inductive component 1.

It is also possible, as illustrated in FIG. 6, for the device DIS to include in the coating 3 and in the zone Z2 distinct from the zone Z1 at least one integrated circuit chip 8.

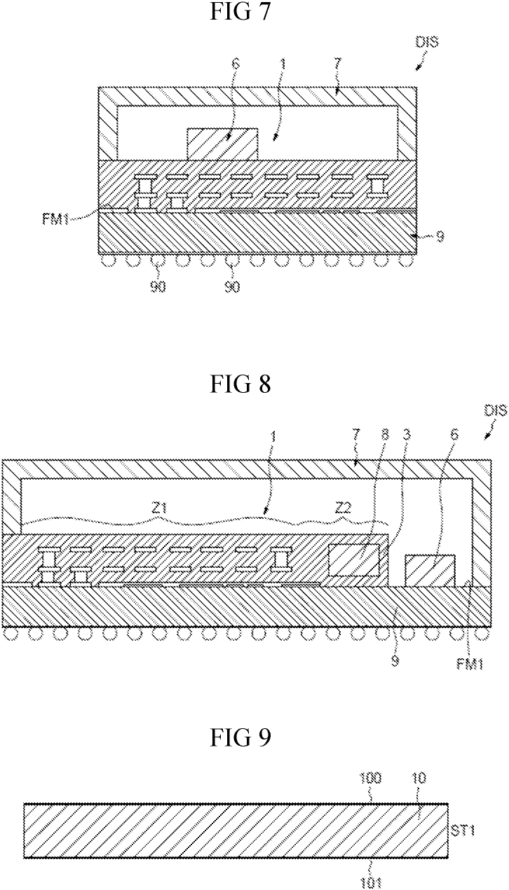

While in FIGS. 4 to 6, the coating 3 forms a supporting substrate, the device DIS can include, as schematically illustrated in FIGS. 7 and 8, a supporting substrate 9 distinct from the inductive component 1.

This supporting substrate 9 can be a multilayer conventional substrate equipped on its lower face with electrically conductive connection 90, here again for example, but not limitingly, solder balls, to allow the fastening of this supporting substrate 9 onto a printed circuit board for example.

Opposite to this lower face, the supporting substrate includes a mounting face FM1 supporting the inductive component 1.

Here again, as illustrated in FIG. 7, the device DIS can include an electronic integrated circuit chip 6 supported by the inductive component 1 and located above the metal winding of this inductive component.

An encapsulation body 7, for example a cover or a molding resin, can complete the device DIS in such a way that it forms an integrated circuit package.

It is also possible as illustrated in FIG. 8 for the coating 3 to include an integrated circuit chip 8 located in a zone Z2 distinct from the zone Z1 in which the metal winding of the inductive component 1 is located.

The device DIS can also include at least one electronic integrated circuit chip 6 located laterally with respect to the inductive component 1 and supported by the mounting face of the supporting substrate 9.

Reference is now made more particularly to FIGS. 9 to 20 to describe an embodiment of a method for manufacturing an integrated inductive component.

As illustrated in FIG. 9, in a step ST1, a seed layer 100 and 101 (for example a very fine copper film) is formed on each of the faces 100 and 101 of a metal support 10, for example made of stainless steel.

Then, a first metallization level including in particular contact pads L1, L2 is formed on the layer 100 in a step ST2 (FIG. 10). This first metallization level can also include metal tracks and optionally a first metal track in the shape of a spiral of the metal winding of the future inductive component.

That being said, in the example illustrated here, the first level of metal does not include a metal track in the shape of a spiral of the metal winding of the future inductive component.

The contact pads L2 and L1 as well as the optional other metal tracks of the first metallization level are, for example, formed by electrolytic or (optionally autocatalytic) deposition of copper (plating).

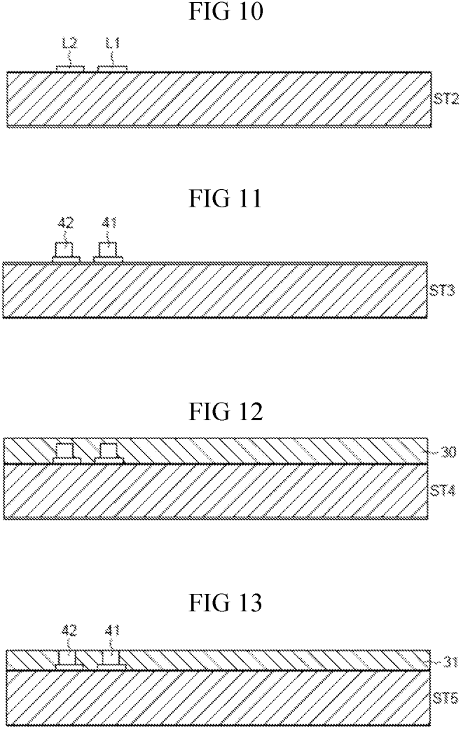

Then, as illustrated in FIG. 11, the first stud or pillar 41 as well as the second stud or pillar 42 are formed, in a step ST3, also by an electrolytic deposition of copper.

Then, in step ST4 (FIG. 12), after having prepared the resin in the form of a viscous material, with the elements indicted above and chosen according to the ferromagnetic properties desired for the intended use, a preliminary layer 30 of resin is deposited so as to embed the pillars 41 and 42.

This formation of the layer 30 is carried out, for example, by injection of the viscous resin at 175° C., with a transfer pressure of 8 MPa and a pressure on the substrate of 350 kN, then a polymerization, for example by cooling to ambient temperature or with optionally an ultraviolet radiation, of this viscous layer is carried out so as to solidify the resin.

Then in step ST5 (FIG. 13) a thinning of the preliminary layer 30 is carried out, for example by chemical mechanical polishing, so as to obtain a first layer 31 of hardened ferromagnetic resin letting the upper faces of the studs 41 and 42 be exposed.

Then in step ST6 (FIG. 14), also for example by formation of a metal attachment layer followed by an electrolytic deposition (growth) of copper, the formation of the second metallization level including here the first metal track 20 in the shape of a spiral of the metal winding of the future inductive component is carried out.

This first metal track 31 comes in contact with the exposed upper face of the first stud 41.

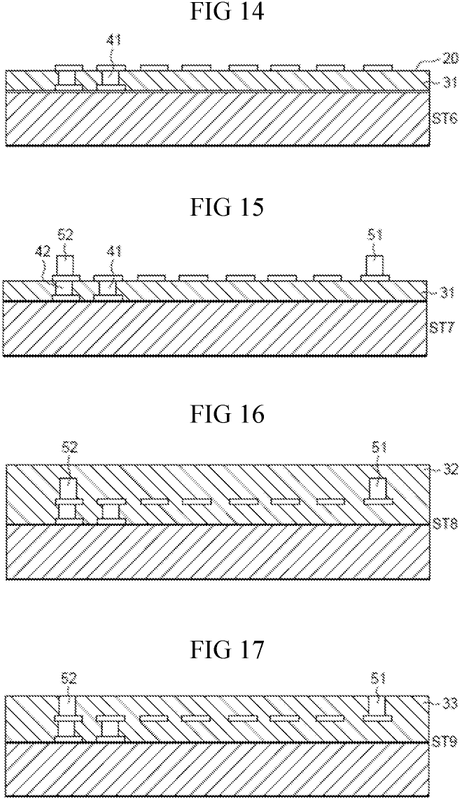

Then, in step ST7 (FIG. 15), the two vias 51 and 52 respectively coming in contact with the second end of the first metal track 20 and the exposed upper face of the second stud 42 are formed, also by electrolytic deposition of copper.

Then, in step ST8 (FIG. 16), the structure obtained in step ST7 is covered by a new layer 32 of ferromagnetic resin.

The formation of this layer 32 is carried out under the same conditions as those for the formation of the layer 30 of FIG. 12.

A thinning of this layer 32, for example by chemical mechanical polishing, is then carried out in step ST9 of FIG. 17 so as to obtain a second layer 33 of ferromagnetic resin leaving free the upper faces of the vias 51 and 52.

Then, in step ST10 (FIG. 18), a second metal track 21 in the shape of a spiral of the metal winding of the inductive component having an end connected to the free upper face of the via 51 and another end connected to the free upper face of the via 52 is formed, also by electrolytic deposition of copper.

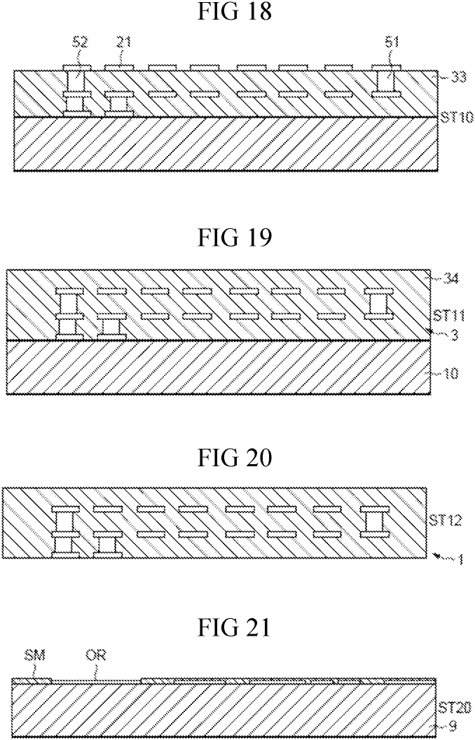

Then, in step ST11 (FIG. 19), the structure obtained in step ST10 is covered with a third layer of ferromagnetic resin. The formation of this third layer 34 is analogous to the formation of the previous layers of resin.

Finally, in step ST12 (FIG. 20), the metal support 10 is removed so as to obtain the component 1 illustrated in FIG. 1.

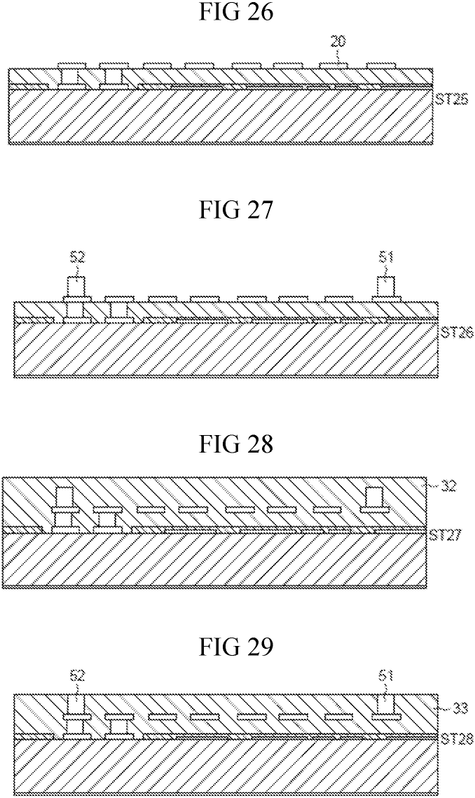

Reference is now made more particularly to FIGS. 21 to 31 to illustrate another embodiment of a method for manufacturing a device.

In this embodiment, the metal support 10 of FIG. 9 is replaced in FIG. 21 by a supporting substrate 9, for example a conventional multilayer supporting substrate of an integrated circuit package.

Then, in step ST20 (FIG. 21), the pattern of a first metallization level is defined using a mask SM.

This mask allows to define an orifice OR in which in particular the contact pads L1 and L2 analogous to the contact pads L1 and L2 of FIG. 10 are defined in step ST21 of FIG. 22.

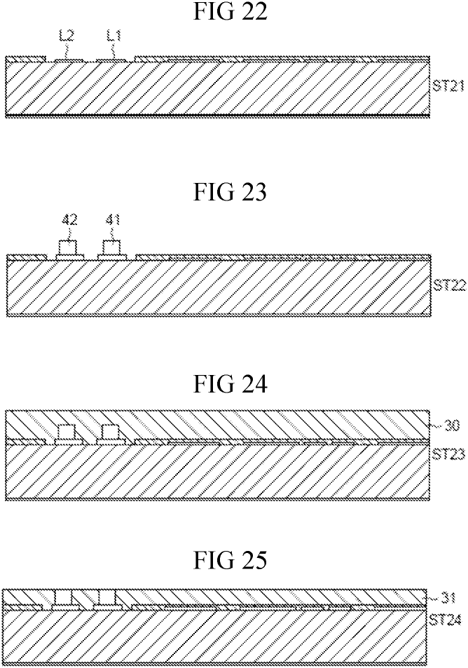

Steps ST22 to ST30 (FIGS. 23-31) are analogous to steps ST3 to ST11 (FIGS. 11-19) described above.

After step ST30, the component 1 of FIG. 7 supported by the supporting substrate 9 is obtained.

Unlike the embodiment illustrated in FIGS. 9 to 20, the supporting substrate 9 is not removed after step ST30.

Of course, if it is desired to create an inductor having more than two metal tracks in the shape of spirals, steps ST7 to ST11 or ST 26 to ST30 can be repeated as many times as necessary.

The invention is not limited to the embodiments and implementations that have just been described.

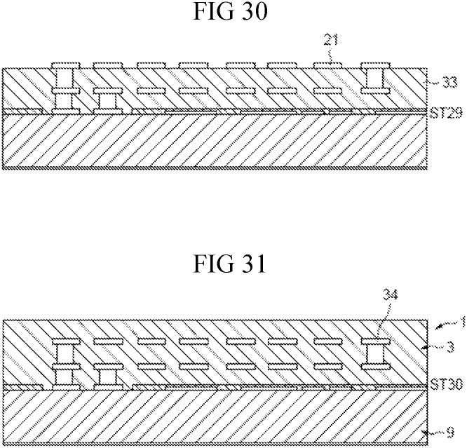

Thus, once created after step ST12, the component 1 of FIG. 20 could be welded onto a printed circuit board so as to obtain the structure illustrated in FIG. 31.

It is also possible to replace certain ferromagnetic layers by non-magnetic layers, for example dielectric.

Thus, for example, in FIGS. 16, 17 and FIGS. 28, 29, the layers 32 and 33 could be dielectric layers, which allows to have in the coating 3 of the component 1 of FIG. 1 (or of FIG. 7) a dielectric layer between the turns 20 and 21 and thus to decouple them.

1. An integrated circuit device, comprising:
an inductive component formed by one or more integrated metal windings, wherein each integrated metal winding is at least partially embedded in a coating including at least one ferromagnetic material.

2. The integrated circuit device according to claim 1, wherein the coating further includes a non-magnetic material.

3. The integrated circuit device according to claim 1, wherein each integrated metal winding includes at least one flat integrated metal track having a shape suitable for creating an inductor.

4. The integrated circuit device according to claim 3, wherein each integrated metal winding includes several flat integrated metal tracks respectively located in parallel planes, electrically connected and mutually separated from each other by the ferromagnetic material.

5. The integrated circuit device according to claim 4, wherein some flat integrated metal tracks are mutually separated by the non-magnetic material.

6. The integrated circuit device according to claim 1, wherein each integrated metal winding is totally embedded in said coating.

7. The integrated circuit device according to claim 1, wherein each integrated metal winding includes two ends, wherein the coating includes several faces, and further including two integrated metal contacts respectively connected to the two ends and opening onto at least one of the faces.

8. The integrated circuit device according to claim 1, wherein said coating forms a supporting substrate having two opposite faces.

9. The integrated circuit device according to claim 8, wherein one of the faces is a mounting face and the other face includes an electrically conductive connection.

10. The integrated circuit device according to claim 9, further including an encapsulation body fastened onto the mounting face so as to form an integrated circuit package.

11. The integrated circuit device according to claim 8, wherein the coating further includes at least one integrated circuit chip located in the coating in a first zone distinct from a second zone containing the integrated metal winding.

12. The integrated circuit device according to claim 8, wherein one of the faces is a mounting face, wherein the mounting face of the coating also supports at least one electronic integrated circuit chip encapsulated by an encapsulation body fastened onto the mounting face so as to form an integrated circuit package.

13. The integrated circuit device according to claim 1, further comprising a supporting substrate having a mounting face supporting said inductive component.

14. The integrated circuit device according to claim 13, including at least one electronic integrated circuit chip, said inductive component supporting said at least one electronic integrated circuit chip.

15. The integrated circuit device according to claim 13, wherein the supporting substrate also supports at least one electronic integrated circuit chip located on the mounting face laterally with respect to said inductive component.

16. The integrated circuit device according to claim 13, further including at least one integrated circuit chip located in the coating in a zone distinct from a zone containing the metal winding.

17. The integrated circuit device according to claim 13, further including an encapsulation body fastened onto the mounting face and encapsulating said inductive component and at least one integrated circuit chip, so as to form an integrated circuit package.

18. A method for integrated circuit manufacture of an inductive component, comprising:
a) forming by integrated circuit manufacturing techniques at least one integrated metal winding at least partially embedded in a coating including at least one ferromagnetic material.

19. The method according to claim 18, wherein the integrated metal winding includes at least one first flat integrated metal track in the shape of a spiral, and step a) includes:
a1) forming, above a first face of a support, a first layer of the ferromagnetic material having a free face; and
a2) forming said at least one first flat integrated metal track in the shape of a spiral on said free face.

20. The method according to claim 19, further comprising, after step a2):
a3) forming a second layer of the ferromagnetic material encapsulating said at least one first flat integrated metal track.

21. The method according to claim 20, further comprising, before step a1),
a0) forming a first electrically conductive stud and a second electrically conductive stud above the first face of the support, respectively intended to be in contact with a first end and a second end of the integrated metal winding.

22. The method according to claim 21, wherein the first electrically conductive stud is in contact with a first end of the first flat integrated metal track and the second electrically conductive stud is not in contact with this first flat integrated metal track, and wherein step a) comprises, after step a2) and before step a3):
a20) forming a first electrically conductive via and a second electrically conductive via respectively connecting a second free end of the first flat integrated metal track and the second electrically conductive stud; and
after step a3):
a4) forming a second flat integrated metal track in the shape of a spiral on the second layer of ferromagnetic material, the two ends of this second flat integrated metal track respectively contacting the first and second electrically conductive vias.

23. The method according to claim 22, further comprising, after step a4):
a5) form a third layer of the ferromagnetic material encapsulating said second flat integrated metal track.

24. The method according to claim 19, further comprising a removal of the support after step a).

25. The method according to claim 19, wherein the support is a multilayer supporting substrate that is preserved after step a).

26. The method according to claim 18, comprising a replacement of a layer of ferromagnetic material by a layer of a non-magnetic material so as to obtain at least one non-magnetic layer adjacent to a ferromagnetic layer.
